(19) United States
(12) Patent Application Publication
(10) Pub. No.: US 2013/0093022 A1
(43) Pub. Date: Apr. 18, 2013

(54) SEMICONDUCTOR DEVICE

(71) Applicant: Hyun-Seung CHOI, Gyeonggi-do (KR)

(72) Inventor: Hyun-Seung CHOI, Gyeonggi-do (KR)

(21) Appl. No.: 13/607,025

(22) Filed: Sep. 7, 2012

(30) Foreign Application Priority Data
Oct. 18, 2011 (KR) 10-2011-0106427

(51) Int. Cl. H01L 27/092; H01L 29/78

(52) U.S. Cl. 257/369; 257/288; 257/E27.062; 257/E29.255

(57) ABSTRACT

A semiconductor device includes a transistor area includes a transistor area comprising a transistor formed in the transistor area at a transistor level, wherein a gate of the transistor is formed at a gate level; a first metal line formed across the transistor area at a first level higher than the transistor level to supply a power voltage to the transistor; and a gate metal line formed at the gate level to supply the power voltage to the transistor area, and the gate metal line is electrically coupled to the first metal line.

### CROSS-REFERENCE TO RELATED APPLICATIONS

The present application claims priority of Korean Patent Application No. 10-2011-0106427, filed on Oct. 18, 2011, which is incorporated herein by reference in its entirety.

### BACKGROUND

1. Field

Exemplary embodiments of the present invention relate to a semiconductor device.

2. Description of the Related Art

According to the increasing demand for high integration and high speed semiconductor devices, a variety of attempts to store a larger amount of information in a smaller area have been made. In particular, the demand for high integration and high speed has been satisfied through circuit design.

As the design rule of semiconductor devices shrinks to implement high integration, a distance between a circuit included in a semiconductor device formed in a wafer and a pattern for supplying a signal voltage applied to the circuit decreases. Furthermore, reducing the sizes of circuits and various lines included in the semiconductor device and effectively arranging the circuits and the lines become an important issue of semiconductor device design.

Meanwhile, a method for reducing power consumed in a semiconductor device, in addition to high integration and high speed, may be useful. The voltage level of power supplied to a semiconductor device may be decreased in order to reduce the power. As the voltage level of power supplied gradually decreases, methods for effectively transmitting a low-level voltage to a circuit included in the semiconductor device may also be useful.

### SUMMARY

An embodiment of the present invention is directed to a semiconductor device that is capable of effectively supplying power to transistors included in the semiconductor device and increasing the uniformity of patterns.

In accordance with an embodiment of the present invention, a semiconductor device includes: a transistor area comprising a transistor formed in the transistor area at a transistor level, wherein a gate of the transistor is formed at a gate level; a first metal line formed across the transistor area at a first level higher than the transistor level to supply a power voltage to the transistor; and a gate metal line formed at the gate level to supply the power voltage to the transistor area, and the gate metal line is electrically coupled to the first metal line.

In accordance with another embodiment of the present invention, a semiconductor device includes: a PMOS area comprising a PMOS transistor formed in the PMOS area at a transistor level, wherein a gate of the PMOS transistor is formed at a gate level; a first metal line formed across the PMOS area at a first level higher than the transistor level to supply a power supply voltage to the PMOS transistor; a first gate metal line formed at the gate level to supply the power supply voltage to the PMOS area, and the first metal gate metal line is electrically coupled to the first metal line; an NMOS area spaced apart from the PMOS area and comprising an NMOS transistor formed in the NMOS area at a transistor level, wherein a gate of the PMOS transistor is formed at the gate level; a second metal line formed across the NMOS area at the first level to supply a ground voltage to the NMOS transistor; and a second gate metal line formed at the gate level to supply the ground voltage to the NMOS area, and the second gate metal line is electrically coupled to the second metal line.

In accordance with yet another embodiment of the present invention, a semiconductor device includes: a transistor comprising an active area formed at an active area level and a gate formed at a gate level higher than the active area level and adjacent to the active area; a gate metal line formed at the gate level to supply a power voltage to the transistor; a first metal line formed at a first level higher than the gate level to supply the power voltage to the transistor, and the first metal line is electrically coupled to the gate metal line; and a second metal line formed at a second level higher than the gate level and lower than the first level coupled to the active area of the transistor through a first contact, coupled to the gate metal line through a second contact, and coupled to the first metal line through a third contact.

### BRIEF DESCRIPTION OF THE DRAWINGS

FIG. 1 is a configuration diagram of a semiconductor device in accordance with an embodiment of the present invention.

FIG. 2 is a cross-sectional view taken along a line AB of FIG. 1.

FIG. 3 is a cross-sectional taken along a line CD of FIG. 1.

FIG. 4 is a configuration diagram of a semiconductor device in accordance with another embodiment of the present invention.

FIG. 5 is a cross-sectional view taken along a line AB of FIG. 4.

FIG. 6 is a cross-sectional view taken along a line CD of FIG. 4.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

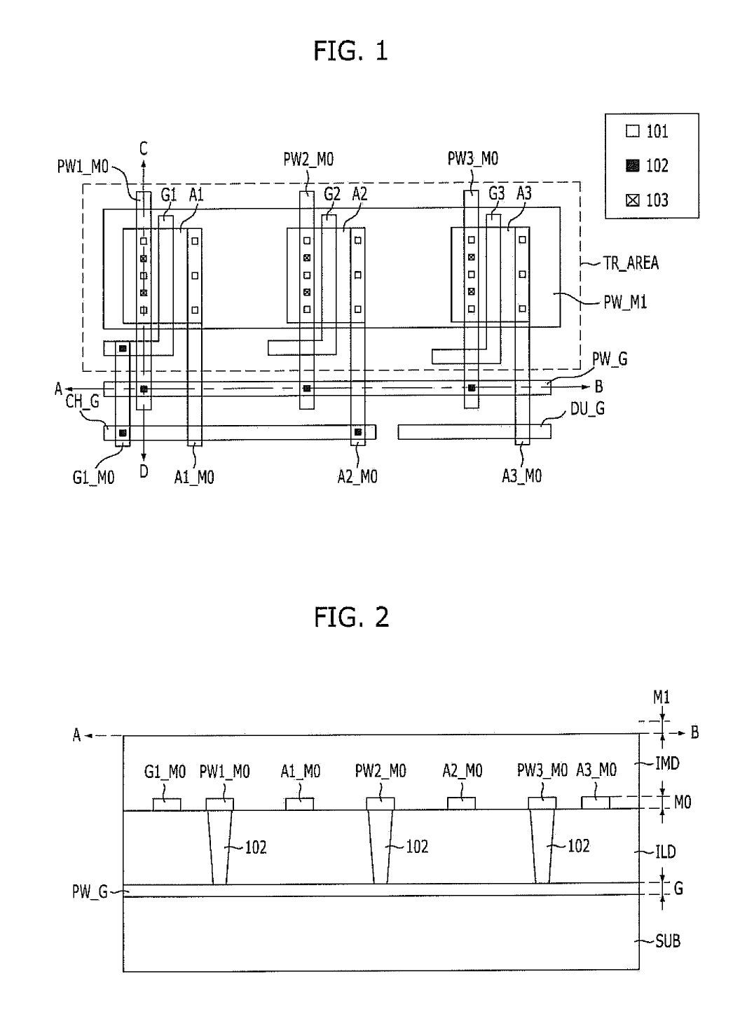

FIG. 1 is a configuration diagram of a semiconductor device in accordance with an embodiment of the present invention.

Referring to FIGS. 1 to 3, the semiconductor device includes a transistor area TR_AREA, one or more first metal lines PW_M1, and one or more gate metal lines PW_G. The transistor area TR_AREA is where one or more transistors G1 and A1 to G3 and A3 are formed. Here, GN and AN represents a transistor including a gate GN and an active area AN. The first metal line PW_M1 is formed across the transistor area TR_AREA at a first level higher than a level where the transistors G1 to A1 to G3 and A3 are formed to supply a power voltage to the transistors G1 to A1 to G3 and A3. The gate metal line PW_G is formed at a gate level equal to the level of the gates G1 to G3 of the transistors, and the gate metal line PW_G is electrically coupled to the corresponding first metal line among the one or more first metal lines PW_M1. Furthermore, the semiconductor device includes one or more second metal lines PW1_M0 to PW3_M0 and one or more dummy gate metal lines DU_G. The second metal lines PW1_M0 to PW3_M0 are formed at a second level that is lower than the first level and higher than the gate level, and the second metal lines PW1_M0 to PW3_M0 are coupled to the corresponding first metal line among the one or more first metal lines PW_M1, the corresponding transistors among the one or more transistors G1 and A1 to G3 and A3, and the corresponding gate metal line among the one or more gate metal lines PW_G through contacts 101 to 103. The dummy gate metal line DU_G is formed at the gate level in a direction parallel to the gate metal line PW_G. A transistor level is a level where an active region of MOS transistor is formed. A gate level is a level where a gate of MOS transistor is formed.

Hereafter, referring to FIG. 1, the semiconductor device will be described in more detail.

The transistor area TR_AREA includes one or more transistors G1 and A1 to G3 and A3 formed in the transistor area TR_AREA. As an example, FIG. 1 illustrates three transistors formed in the transistor area TR_AREA. The transistors include gates G1 to G3 and active areas A1 to A3, respectively. The transistors G1 and A1 to G3 and A3 may include a CMOS transistor.

To supply a power voltage to the transistors G1 and A1 to G3 and A3 formed in the transistor area TR_AREA, one or more first metal lines PW_M1 are formed across the transistor area TR_AREA. As an example, FIG. 1 illustrates one first metal line formed in the transistor area TR_AREA. The first metal line PW_M1 is electrically coupled to the active areas A1 to A3 of the transistors. Through the first metal line PW_M1, a power voltage may be applied to sources of the transistors.

When the transistors G1 and A1 to G3 and A3 formed in the transistor area TR_AREA are PMOS transistors, the power voltage applied to the first metal line PW_M1 may include a power supply voltage VDD. When the transistors G1 and A1 to G3 and A3 formed in the transistor area TR_AREA are NMOS transistors, the power voltage applied to the first metal line PW_M1 may include a ground voltage VSS.

One or more gate metal lines PW_G are formed at the gate level, and the metal gate lines PW_G are electrically coupled to the first metal line PW_M1. As an example, FIG. 1 illustrates one gate metal line PW_G formed at the gate level. The gate metal line PW_G corresponds to an additional metal line for transmitting a power voltage to the transistors G1 and A1 to G3 and A3. Therefore, as the gate metal line PW_G is formed, the transmission efficiency of power transmitted to the active areas A1 to A3 of the transistors increases.

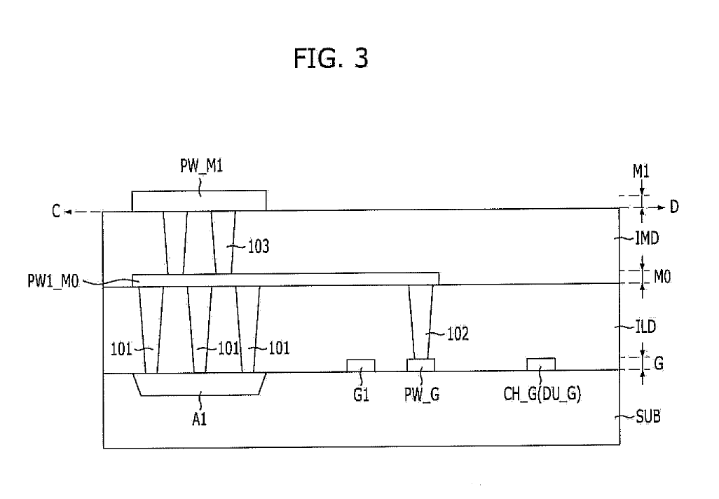

One or more second metal lines PW1_M0 to PW3_M0 are formed at the second level, which is higher than the gate level and lower than the first level. As an example, FIG. 1 illustrates three second metal lines formed at the second level. The second metal lines PW1_M0 to PW3_MO couple the first metal line PW_M1 and the active areas A1 to A3 of the transistors, respectively, to the gate metal line PW_G through the contacts 101 to 103. The coupling through the contacts 101 to 103 will be described with reference to FIGS. 2 and 3.

One or more dummy gate metal lines DU_G are formed in the upper or lower side of the transistor area TR_AREA, and the one or more dummy gate metal lines DU_G are formed in a direction parallel to the gate metal line PW_G at the gate level. As an example, FIG. 1 illustrates one dummy gate metal line formed in the lower side of the transistor area. The dummy gate metal line DU_G is a metal line for increasing the uniformity of patterns, and the dummy gate metal line DU_G is not electrically coupled to other components of the semiconductor devices. For reference, the upper or lower side indicates the upper or lower direction of the transistor area TR_AREA on a plane including the transistor area TR_AREA.

Furthermore, the semiconductor device may include one or more third metal lines G1_M0, one or more fourth metal lines A1_M0 to A3_M0, and a fifth metal line CH_G. As an example, FIG. 1 illustrates that one third metal line and three fourth metal lines are formed. The third metal line G1_M0 is formed at the second level to apply a signal to the gates G1 to G3 of the transistors. The fourth metal lines A1_M0 to A3_M0 are formed at the second level to transmit signals outputted from the active area A1 to A3 of the transistors. The fifth metal line CH_G is configured to couple the third metal line G1_M0 to the fourth metal lines A1_M0 to A3_M0. Through the fifth metal line CH_G, signals applied to the transistors G1 and A1 to G3 and A3 or signals outputted from the transistors G1 and A1 to G3 and A3 are transmitted. The third metal line G1_M0 may be coupled to the gates G1 to G3 of the transistors through one or more contacts 102, and the fourth metal lines A1_M0 to A3_M0 may be coupled to the active areas A1 to A3 of the transistors, respectively, through one or more contacts 101.

The semiconductor device in accordance with the embodiment of the present invention includes the gate metal line PW_G formed at the gate level to increase the transmission efficiency of the power voltage transmitted to the active areas A1 to A3 of the transistors. Furthermore, the dummy gate metal line DU_G is formed to increase the uniformity of patterns to reduce issues occurring due to a stress caused by a shallow trench isolation (STI) process or the like.

FIG. 2 is a cross-sectional view taken along a line AB of FIG. 1. FIG. 3 is a cross-sectional taken along a line CD of FIG. 1. Hereafter, referring to FIGS. 1 to 3, the semiconductor device will be described, and the following descriptions will be focused on the vertical structure.

Referring to FIGS. 1 to 3, the semiconductor device includes the transistors G1 and A1 to G3 and A3, the gate metal line PWG, the first metal line PW_M1, the second metal lines PW1_M0 to PW3_M0, and the gate metal line DUG. The transistors G1 and A1 to G3 and A3 include active areas A1 to A3 and gates G1 to G3 formed at the gate level G, which is higher than the active areas A1 to A3 and adjacent to the active areas A1 to A3. The gate metal line PW_G is formed at the gate level to supply a power voltage to the transistors G1 and A1 to G3 and A3. The first metal line PW_M1 is formed at the first level M1 higher than the gate level G to supply a power voltage to the transistors G1 and A1 to G3 and A3 and electrically coupled to the gate metal line PW_G. The second metal lines PW1_M0 to PW3_M0 are formed at the second level M0 higher than the gate level G and lower than the first level M1, the second metal lines PW1_M0 to PW3_M0 are coupled to the respective active areas A1 to A3 of the transistors G1 and A1 to G3 and A3 through one or more first contacts 101, the second metal lines PW1_M0 to PW3_M0 are coupled to the gate metal line PW_G through one or more second contacts 102, and the second metal lines PW1_M0 to PW3_M0 are coupled to the first metal line PW_M1 through one or more third contacts 103. The dummy gate metal line DU_G is formed at the gate level G in a direction parallel to the gate metal line PW_G.

Furthermore, the semiconductor device includes a first insulation layer ILD formed between the second level M0 and a substrate SUB having the active areas A1 to A3 formed in the first insulation layer ILD and a second insulation layer IMD formed between the second level M0 and the first level M1. The first insulation layer ILD electrically insulates the metal lines formed in the active areas A1 to A3 and at the gate level G from the metal lines formed at the second level M0. The second insulation layer IMD electrically insulates the metal lines formed at the second level M0 from the metal lines formed at the first level M1. The first insulation layer ILD may includes an interlayer dielectric layer, and the second insulation layer IMD may include an intermetal dielectric layer.

The components formed at different levels are coupled through contacts. Specifically, the metal lines formed in the active areas A1 to A3 at the second level M0 are electrically through the first contacts 101, the metal lines formed at the gate level G and the metal lines formed at the second level M0 are electrically coupled through the second contacts 102, and the metal lines formed at the second level M0 and the metal lines formed at the first level M1 are electrically coupled through the third contacts 103. Furthermore, the insulation layers are formed between the respective levels so that the components are electrically coupled, fore example, only through the contacts. The insulation layer may include BPSG (BoroPhosphoSilicate Glass), PSG (PhosphoSilicate Glass), FSG (Fluorinated Silicate Glass), HDP (High Density Plasma), TEOS (Tetra Ethyle Ortho Silicate), or the like.

The descriptions of other configuration are the same as the descriptions described with reference to FIG. 1. In the semiconductor device in accordance with the embodiment of the present invention, a metal line is not additionally formed at the first and second levels M1 and M2, but the metal lines PW_G and DU_G are additionally formed at the gate level G. Therefore, the transmission efficiency of the power voltage supplied to the transistors G1 and A1 to G3 and A3 increases, and the uniformity of patterns increases.

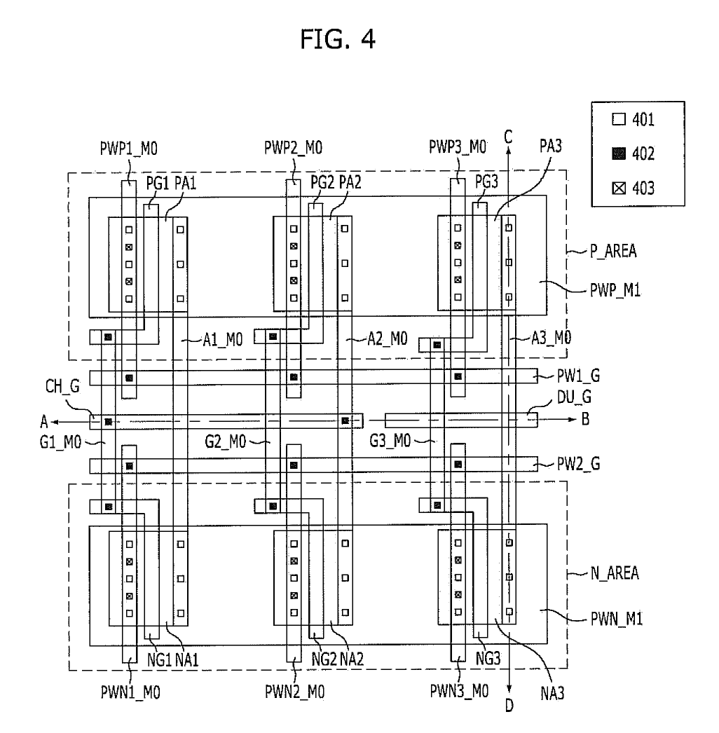

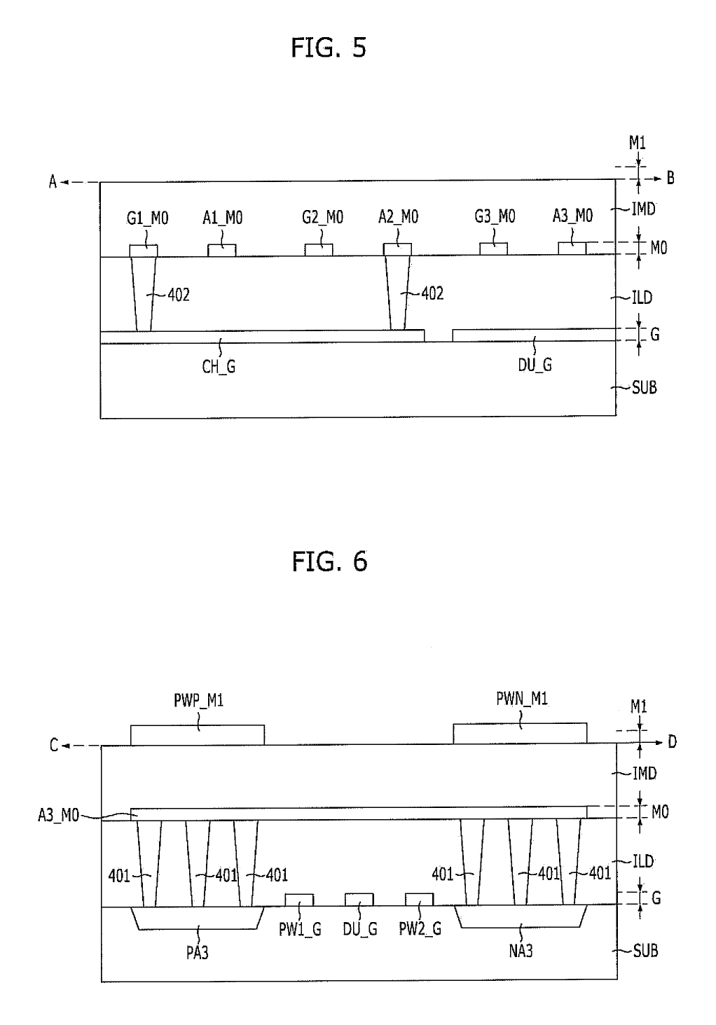

FIG. 4 is a configuration diagram of a semiconductor device in accordance with another embodiment of the present invention. FIG. 5 is a cross-sectional view taken along a line AB of FIG. 4. FIG. 6 is a cross-sectional view taken along a line CD of FIG. 4. FIG. 4 illustrates a semiconductor device including a PMOS area P_AREA and an NMOS area N_AREA, which are symmetrically formed. The semiconductor device of FIG. 4 corresponds to a semiconductor device where the semiconductor devices of FIG. 1 are symmetrically arranged in the upper and lower sides.

Referring to FIGS. 4 to 6, the semiconductor device includes a PMOS area P_AREA, one or more first metal lines PWP_M1, one or more first gate metal lines PW1_G, an NMOS area N_AREA, one or more second metal lines PWN_M1, one or more second gate metal lines PW2_G, one or more third metal lines PWP_M0 to PWP3_M0, and one or more fourth metal lines PWN1_NO to PWN3_MO. One or more PMOS transistors PG1 and PA1 to PG3 to PA3 are formed in the PMOS area P_AREA. The first metal line PWP_M1 is formed across the PMOS area P_AREA at a first level M1 higher than a level where the PMOS transistors PG1 and PA1 to PG3 to PA3 are formed in order to supply a power supply voltage to the PMOS transistor PG1 and PA1 to PG3 to PA3. The level where the PMOS transistors PG1 and PA1 to PG3 to PA3 are formed corresponds to the level of a substrate SUB. The first gate metal line PW1_G is formed at a gate level G equal to the level of the gates of the PMOS transistors PG1 and PA1 to PG3 to PA3 to supply a power supply voltage to the PMOS area P_AREA, and the first gate metal line PW1_G is electrically coupled to the first metal line PWP_M1. The NMOS area N_AREA is spaced apart from the PMOS area P_AREA and is where one or more NMOS transistors NG1 and NA1 to NG3 and NA3 are formed. The second metal line PWN_M1 is formed across the NMOS area N_AREA at the first level MI in order to supply a ground voltage to the transistors NG1 and NA1 to NG3 and NA3. The second gate metal line PW2_G is formed at the gate level G to supply a ground voltage to the NMOS area N_AREA, and the second gate metal line PW2_G is electrically coupled to the second metal line PWN_M1. The third metal lines PWP1_M0 to PWP3_M0 are formed at a second level M0 lower than the first level and higher than the gate level G, and the third metal lines PWP1_M0 to PWP3_M0 are coupled to the first metal line PWP_M1, the PMOS transistors PG1 and PA1 to PG3 to PA3, and the gate metal line PW1_G through contacts 401 to 403. The fourth metal lines PWN1_M0 to PWN3_M0 are formed at the second level M0 and coupled to the second metal line PWN_M1, the NMOS transistors NG1 and NA1 to NG3 and NA3, respectively, and the second gate metal line PW2_G through the contacts 401 to 403. The semiconductor device further includes one or more dummy gate metal lines DU_G formed between the PMOS area P_AREA and the NMOS area N_AREA and formed at the gate level G in a direction parallel to the first gate metal line PW1_G and the second gate metal line PW2_G.

Each of the PMOS area P_AREA and the NMOS area N_AREA corresponds to the transistor area TR_AREA of FIG. 1. The PMOS transistors PG1 and PA1 to PG3 to PA3 and the NMOS transistors NG1 and NA1 to NG3 and NA3 include gates PG1 to PG3 and NG1 to NG3 and active areas PA1 to PA3 and NG1 to NG3, respectively. As an example, FIG. 4 illustrates that three PMOS transistors and three NMOS transistors are formed.

The first metal line PWP_M1 is formed across the PMOS area P_AREA to supply a power supply voltage to the PMOS transistors PG1 and PA1 to PG3 to PA3 formed in the PMOS area P_AREA. As an example, FIG. 4 illustrates that one first metal line is formed. Furthermore, the second metal line PWN_M1 is formed across the NMOS area N_AREA to supply a ground voltage to the NMOS transistors NG1 and NA1 to NG3 and NA3. As an example, FIG. 4 illustrates that one second metal line is formed.

The first and second gate metal lines PW1_G and PW2_G are formed at the gate level G, and the first and second gate metal lines PW1_G and PW2_G are electrically coupled to the first and second metal lines PWP_M1 and PWN_M1, respectively. As an example, FIG. 4 illustrates that one first gate metal line, one second gate metal line, one first metal line, and one second metal line are formed. The first and second gate metal lines PWP_G and PWN_G correspond to an additional metal line that transmits a power supply voltage or ground voltage to the PMOS area P_AREA or the NMOS area N_AREA. Therefore, as the first and second gate metal lines PWP_G and the PWN_G are formed, the transmission efficiency of power transmitted to the active areas PA1 to PA3 and NA1 to NA3 of the transistors included in the PMOS area P_AREA or the NMOS area N_AREA increases.

The third and fourth metal lines PWP1_M0 to PWP3_M0 and PWN1_M0 to PWN3_M0 are formed at the second level M0 higher than the gate level G and lower than the first level M1, and the third and fourth metal lines PWP1_M0 to PWP3_M0 and PWN1_M0 to PWN3_M0 are coupled to the first and second metal lines PWP_M1 and PWN_M1, the active areas PA1 to PA3 and NA1 to NA3 of the transistors, and the first and second gate metal lines PWN_G and PWN_G, respectively, through the contacts 401 to 403. As an example, FIG. 4 illustrates that three third metal lines and three fourth metal lines are formed.

The dummy gate metal line DU_G is formed between the PMOS area P_AREA and the NMOS area N_AREA, and the dummy gate metal line DU_G is formed in a direction parallel to the first and second gate metal lines PW1_G and PWN_G at the gate level G. As an example, FIG. 1 illustrates that one dummy gate metal line is formed. The dummy gate metal line DU_G is a metal line for increasing the uniformity of patterns, and the dummy gate metal line DU_G is not electrically coupled to other components of the semiconductor device.

The semiconductor device further includes fifth metal lines G1_M0 to G3_M0 formed at the second level M0 and coupled to the gates NG1 to NG3 of the NMOS transistors NG1 and NA1 to NG3 and NA3 and the gates PG1 to PG3 of the PMOS transistors PG1 and PA1 to PG3 to PA3, respectively, through the contacts 402. More specifically, the gates NG1 to NG3 of the NMOS transistors NG1 and NA1 to NG3 and NA3 and the gates PG1 to PG3 of the PMOS transistors PG1 and PA1 to PG3 to PA3 may be electrically coupled through the fifth metal lines G1_M0 to G3_M0. Through the fifth metal lines G1_M0 to G3_M0, signals may be applied to the gates NG1 to NG3 of the NMOS transistors and the gates PG1 to PG3 of the PMOS transistors.

The semiconductor device further includes sixth metal lines A1_M0 to A3_M0 formed at the second level M0 and coupled to the active areas NA1 to NA3 of the NMOS transistors NG1 and NA1 to NG3 and NA3 and the active areas PA1 to PA3 of the PMOS transistors PG1 and PA1 to PG3 to PA3, respectively, through the contacts 401. More specifically, the active areas of the NMOS transistors NG1 and NA1 to NG3 and NA3 and the PMOS transistors PG1 and PA1 to PG3 to PA3 may be electrically coupled through the sixth metal lines A1_M0 to A3_M0, respectively. Through the sixth metal lines A1_M0 to A3_M0, signals outputted from the active areas NA1 to NA3 of the NMOS transistors and the active areas PA1 to PA3 of the PMOS transistors may be transmitted to other components of the semiconductor device.

Signals applied to the gates PG1 to PG3 of the PMOS transistors and the gates NG1 to NG3 of the NMOS transistors, and signals outputted from the active areas PA1 to PA3 of the PMOS transistors and the active areas NA1 to NA3 of the NMOS transistors may be transmitted to the fifth metal lines G1_M0 to G3_M0 and the sixth metal lines A1_M0 to A3_M0 through a second metal line CH_G coupled through contacts 402.

The descriptions with reference to FIGS. 5 and 6 are substantially the same as the descriptions with reference to FIGS. 2 and 3. The metal lines and so on are formed at the respective levels G, M0, and M1, and the components formed at different levels are coupled through the contacts 401, 402, and 403 corresponding to the contacts 101, 102, and 103 of FIG. 1.

The semiconductor device illustrated in FIGS. 4 to 6 includes the metal lines PWP_G and PWN_G for increasing the power transmission efficiency and the metal line DU_G for increasing the uniformity of patterns, which are formed at the gate level G. Therefore, the semiconductor device has the same effect as the semiconductor device illustrated in FIGS. 1 to 3.

In accordance with the embodiments of the present invention, one or more metal lines are formed at the gate level to supply power to the transistors included in the semiconductor device, and one or more dummy gate metal lines are formed at the gate level to increase the uniformity in the patterns.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a transistor area comprising a transistor formed in the transistor area at a transistor level, wherein a gate of the transistor is formed at a gate level;
a first metal line formed across the transistor area at a first level higher than the transistor level to supply a power voltage to the transistor; and
a gate metal line formed at the gate level to supply the power voltage to the transistor area, and the gate metal line is electrically coupled to the first metal line.

2. The semiconductor device of claim 1, further comprising a second metal line formed at a second level lower than the first level and higher than the gate level, wherein the second metal line is coupled to the first metal line, the transistors, and the gate metal line through contacts.

3. The semiconductor device of claim 1, further comprising a dummy gate metal line formed in an upper or lower side of the transistor area and formed at the gate level in a direction parallel to the gate metal lines.

4. The semiconductor device of claim 1, wherein the transistor includes a PMOS transistor, and the power voltage includes a power supply voltage.

5. The semiconductor device of claim 1, wherein the transistor includes an NMOS transistor, and the power voltage includes a ground voltage.

6. The semiconductor device of claim 3, wherein the dummy gate metal line is not electrically coupled to other components of the semiconductor devices.

7. A semiconductor device comprising:
a PMOS area comprising a PMOS transistor formed in the PMOS area at a transistor level, wherein a gate of the PMOS transistor is formed at a gate level;
a first metal line formed across the PMOS area at a first level higher than the transistor level to supply a power supply voltage to the PMOS transistor;
a first gate metal line formed at the gate level to supply the power supply voltage to the PMOS area, and the first metal gate metal line is electrically coupled to the first metal line;
an NMOS area spaced apart from the PMOS area and comprising an NMOS transistor formed in the NMOS area at a transistor level, wherein a gate of the PMOS transistor is formed at the gate level;
a second metal line formed across the NMOS area at the first level to supply a ground voltage to the NMOS transistor; and
a second gate metal line formed at the gate level to supply the ground voltage to the NMOS area, and the second gate metal line is electrically coupled to the second metal line.

8. The semiconductor device of claim 7, further comprising:
a third metal line formed at a second level lower than the first level and higher than the gate level, wherein the third metal line is coupled to the first metal line, the PMOS transistor, and the first gate metal line through contacts; and
a fourth metal line formed at the second level, wherein the fourth metal line is coupled to the second metal line, the NMOS transistor, and the second gate metal line through contacts.

9. The semiconductor device of claim 7, further comprising a dummy gate metal line formed between the PMOS area and the NMOS area, and the dummy gate metal line is formed at the gate level in a direction parallel to the first gate metal line and the second gate metal line.

10. The semiconductor device of claim 9, wherein the dummy gate metal line is not electrically coupled to other components of the semiconductor devices.

11. The semiconductor device of claim 7, further comprising a fifth metal line formed at the second level, wherein the fifth metal line is coupled to the gate of the NMOS and PMOS transistor through contacts.

12. The semiconductor device of claim 7, further comprising a sixth metal line formed at the second level, wherein the sixth metal line is coupled to a drain of the NMOS and PMOS transistor through contacts.

13. A semiconductor device comprising:
a transistor comprising an active area formed at an active area level and a gate formed at a gate level higher than the active area level and adjacent to the active area;
a gate metal line formed at the gate level to supply a power voltage to the transistor;
a first metal line formed at a first level higher than the gate level to supply the power voltage to the transistor, and the first metal line is electrically coupled to the gate metal line; and
a second metal line formed at a second level higher than the gate level and lower than the first level coupled to the active area of the transistor through a first contact, coupled to the gate metal line through a second contact, and coupled to the first metal line through a third contact.

14. The semiconductor device of claim 13, further comprising a dummy gate metal line formed at the gate level in a direction parallel to the gate metal lines.

15. The semiconductor device of claim 14, wherein the dummy gate metal line is not electrically coupled to other components of the semiconductor devices.

16. The semiconductor device of claim 13, further comprising a first insulation layer formed between the second level and a substrate where the active area is formed, wherein the first insulation layer electrically insulates the active area and the metal line formed at the gate level from the metal line formed at the second level; and
a second insulation layer formed between the second level and the first level, wherein the second insulation layer electrically insulates the metal line formed at the second level from the metal line formed at the first level.

17. The semiconductor device of claim 13, wherein the transistor comprises a PMOS transistor, and the power voltage comprises a power supply voltage.

18. The semiconductor device of claim 13, wherein the transistor comprises an NMOS transistor, and the power voltage comprises a ground voltage.
